(19) United States
(12) Patent Application Publication
(10) Pub. No.: US 2017/0018689 A1
(43) Pub. Date: Jan. 19, 2017

(54) Composite Ceramic Wavelength Converter and Light Source Having Same

(71) Applicant: Zhengbo Yu, Shrewsbury, MA (US)

(72) Inventor: Zhengbo Yu, Shrewsbury, MA (US)

(73) Assignee: OSRAM SYLVANIA Inc., Wilmington, MA (US)

(21) Appl. No.: 15/183,064

(22) Filed: Jun. 15, 2016

Related U.S. Application Data
(60) Provisional application No. 62/193,838, filed on Jul. 17, 2015.

(51) Int. Cl. H01L 33/50; C09K 11/77

(52) U.S. Cl. CPC H01L 33/502; C09K 11/7734

(57) ABSTRACT

There is herein described a composite ceramic wavelength converter having a first phase of an α-SiAlON:Eu phosphor and a second phase of a β-SiAlON:Eu phosphor. The converter may be used in a phosphor-converted light emitting diode to form a light source having a correlated color temperature (CCT) from 2000K to 4500K.

This application claims the benefit, including claiming the benefit under 35 U.S.C. §§119(e), 120, of the earlier provisional application “Composite Ceramic Wavelength Converter and Light source having same” (internal docket no. 2014P01793US) filed as U.S. Ser. No. 62/193,838 filed Jul. 17, 2015.

### TECHNICAL FIELD

This invention relates to light emitting diodes (LEDs) and in particular to phosphor-converted LEDs (pc-LEDs) wherein the light emitted by the LED is at least partially converted by a phosphor into light having a different peak wavelength.

### BACKGROUND OF THE INVENTION

Conventional white-light-emitting phosphor-converted LEDs utilize one or more phosphors to partially absorb blue light emissions from InGaN LEDs in order to convert some of the blue light into a yellow light (also referred to as wavelength conversion.) The combination of the remaining unabsorbed blue light and converted yellow light which is finally emitted by the pc-LED is perceived by a human observer as white. This “white” light may range from a cool white (higher color temperature) having a bluish tint to a warm white (lower color temperature) having a reddish tint.

The typical yellow-emitting phosphor used in a pc-LED is a cerium-activated yttrium aluminum garnet, Y₃Al₅O₁₂:Ce, phosphor (YAG:Ce) which may applied to the LED as a powder dispersed in a silicone resin or as a solid monolithic ceramic converter. The YAG:Ce wavelength converters yield quite efficient (lumens/watt) cool white LEDs but the relatively weak red fluorescence of YAG:Ce means that one or more strongly red-emitting phosphors must be added to produce warm white LEDs. Unfortunately these red-emitting phosphors are not as efficient, forcing designers to make a compromise between efficient cool white LEDs with low color rendering, or less efficient warm white LEDs with higher color rendering. In addition, since more than one type of phosphor is needed, warm white LEDs typically use phosphor mixtures dispersed in silicone resins which are susceptible to degradation by UV radiation and temperatures above 200° C. There is also an increased risk of thermal quenching of the emission and larger color shifts over time and temperature.

Alternative ways to achieve white light with a reasonable CRI include using an UV LED with RGB red, green, and blue phosphors, or coupling a blue LED to RG phosphors. The latter alternative requires efficient green and red phosphors that should have an excitation wavelength matching with the emission wavelength of the blue LEDs (450-470 nm). Currently, green phosphors used for white LEDs are mostly based on oxides or sulfides (e.g. ZnS:Cu, Al) and tend to have low chemical and thermal stabilities causing the chromaticity to have a strong temperature dependence and degrading the luminous efficiency of the white LEDs.

### SUMMARY OF THE INVENTION

It is an object of the invention to obviate the disadvantages of the prior art.

It is another object of the invention to provide a composite ceramic wavelength converter for use in a pc-LED.

It is a further object of the invention to provide a light source that may be used in warm white pc-LED applications.

In accordance with one object of the invention, there is provided a composite ceramic wavelength converter that may be used for warm white pc-LEDs. The composite wavelength converter comprises a combination of rare-earth doped oxynitride and nitride phosphors that have been found to have longer excitation and emission wavelengths compared to oxide phosphors. In particular, the composite ceramic wavelength converter comprises a β-SiAlON:Eu phosphor, an α-SiAlON:Eu phosphor and optionally a CaAlSiN₃:Eu phosphor. When the converter is combined with a blue-emitting LED, a warm white pc-LED may be achieved that has a desirable CRI and better thermal and quenching stability.

In accordance with another object of the invention, there is provided a light source comprising a light-emitting diode and a composite ceramic wavelength converter. The light-emitting diode emits a primary light that is at least partially converted by the composite ceramic wavelength converter into a secondary light of a different wavelength. The composite ceramic wavelength converter comprises a first phase of an α-SiAlON:Eu phosphor and a second phase of a β-SiAlON:Eu phosphor wherein a weight ratio of the α-SiAlON:Eu phosphor to the β-SiAlON:Eu phosphor is in a range of about 3:1 to about 1:3.

### BRIEF DESCRIPTION OF THE DRAWINGS

FIG. 1 is an illustration of the color space defined by a blue LED, a green β-SiAlON:Eu phosphor and an amber α-SiAlON:Eu/red CaAlSiN₃:Eu system.

FIG. 2 is a comparison of the emission spectra of an α-CaSiAlON:Eu phosphor sintered with and without sintering aids.

FIG. 3 is an illustration of the use of an α/β-SiAlON composite ceramic wavelength converter in a phosphor-converted LED (pc-LED) configuration.

FIG. 4 shows the emission spectrum of an exemplary α/β-SiAlON composite ceramic wavelength converter.

### DETAILED DESCRIPTION OF THE INVENTION

For a better understanding of the present invention, together with other and further objects, advantages and capabilities thereof, reference is made to the following disclosure and appended claims taken in conjunction with the above-described drawings.

References to the color of a phosphor, LED, or conversion material refer generally to its emission color unless otherwise specified. Thus, a blue LED emits a blue light, a yellow phosphor emits a yellow light and so on.

As used herein the term “ceramic wavelength converter” refers to a solid monolithic piece comprised of at least one sintered, polycrystalline luminescent material, such as an inorganic phosphor, that converts at least a portion of the light from an excitation source to light of a different wavelength. The ceramic converter has a density that is preferably at least about 90% of the theoretical density of the material(s) that comprises it. More preferably, the ceramic wavelength converter has a density that is at least about 95% of theoretical density.

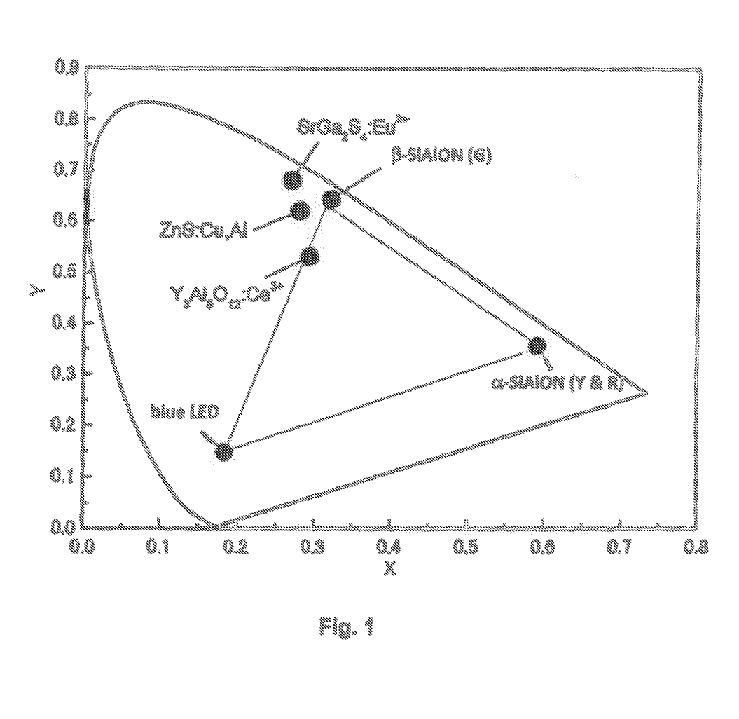

The composite ceramic wavelength converter of the present invention is primarily comprised of α- and β-SiAlON:Eu phosphors which have been proven to have high thermal and chemical stabilities. More importantly, α- and β-SiAlON have a good physical and chemical compatibility, which insures that these phosphors will not react at sintering temperatures. The crystal structures of the above mentioned phosphors may be identified by x-ray diffraction (XRD) techniques. FIG. 1 illustrates the color space defined by a blue LED, a green β-SiAlON:Eu phosphor and an amber α-SiAlON:Eu/red CaAlSiN₃:Eu phosphor system.

In one embodiment, the α-SiAlON:Eu is orange/red-emitting and preferably has a red-shifted excitation spectrum and a narrower emission band which is desirable for warm white pc-LED applications. The α-SiAlON:Eu phosphor preferably has a solid solution composition that may be represented by the formula (M₁₋ₓEUₓ)_{m/v}Si₁₂₋₍ₘ₊ₙ₎Al₍ₘ₊ₙ₎OₙN₁₆₋ₙ, where M is a metal selected from Li, Ca, Mg, Y, La, Ce, Nd, Sm, Gd, Tb, Dy, and Yb, v is the valence of the metal M, 0.5≦m/v≦2, 0.001≦n≦1.8, 0.001≦x≦0.2. More preferably, the α-SiAlON:Eu phosphor has a composition wherein 0.5≦m/v≦2, 0.001≦n≦1.0, and 0.02≦x≦0.1. Even more preferably, M is Ca and the phosphor has an amber-colored emission.

The β-SiAlON:Eu phosphor is preferably green-emitting. The β-SiAlON:Eu phosphor exhibits a large crystal-field splitting and nephelauxetic effect because of the strong covalent nature imparted by the nitrogen atoms and demonstrates a much smaller thermal quenching than comparable oxides and sulfides. The β-SiAlON:Eu phosphor preferably has a solid solution composition that may be represented by the formula Si_{6-z}Al_{z}O_{z}N_{8-z}:Eu, where 0.001≦z≦4.2 and more preferably 0.1≦z≦2. The β-SiAlON:Eu phosphor preferably contains from 0.1% to 8 mole % Eu (with respect to the Si_{6-z}Al_{z}O_{z}N_{8-z}:Eu formulation). More preferably, the β-SiAlON:Eu phosphor contains from 0.2% to 4 mole % Eu.

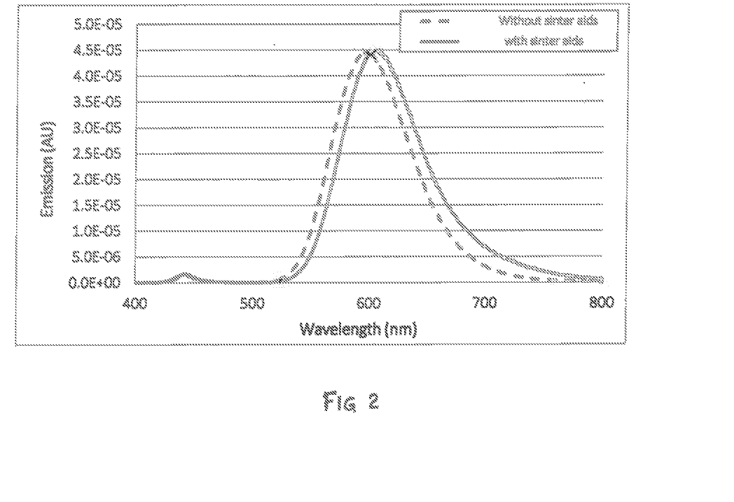

In a preferred embodiment, the introduction of very small amounts (e.g. 0.01 to 7 weight percent (wt %)) of Y₂O₃, Al₂O₃ and SiO₂ sintering aids into an amber-emitting α-CaSiAlON:Eu enables the materials to be densified at lower temperatures and results in a red shift (˜5 nm) in emission, which is desirable for warm-white applications (FIG. 2). A preferred amber α-CaSiAlON:Eu has a formulation (Ca_{1.87}Eu_{0.12})Si_{7.32}Al_{4.68}O_{0.7}N_{15.3}. It is believed the addition of the very small amount of sintering aids (Y₂O₃, Al₂O₃, SiO₂) may significantly increase the sintering driving force to obtain a dense composite warm white ceramic converter.

Densification of the composite ceramic wavelength converter may be achieved by either pressureless sintering or, preferably, spark plasma sintering (SPS). Oxynitrides and/or nitrides phosphors are known to be difficult in achieving dense parts because of their very low bulk diffusion coefficient, i.e., low rate of mass transportation. Thus, high temperatures and long dwell times are normally required to obtain dense parts. In a preferred method, spark plasma sintering (SPS) allows densification of the mixed oxynitride/nitride phosphors with a small amount of the above-described sintering aids which may be used alone or preferably in combination. Densification at lower temperatures reduces the risk of reaction caused by high temperatures and longer sintering times. Hot pressing (HP), hot isostatic pressing (HIP), gas pressure sintering (GPS) and over pressure sintering (OPS) are other possible alternative methods for sintering composite α/β-SiAlON:Eu ceramic converters, especially for dense parts.

Preferred phosphor powders for use in the sintering methods for forming the composite ceramic wavelength converter are:

(i) Amber α-CaSiAlON:Eu phosphor powder with a particle size (d50) of 1.0 to 15 μm containing 1 to 10 atomic percent (at %) Eu, and more preferably 0.5 to 9 at % Eu;

(ii) Green β-SiAlON:Eu phosphor powder with a particle size (d50) of 1.0 to 15 μm containing 0.01 to 2 at % Eu, and more preferably 0.02 to 1 at % Eu; and optionally

(iii) Red CaSiAlN₃:Eu phosphor powder with a particle size (d50) of 1.0 to 15 μm containing 0.01 to 5 at % Eu, and more preferably 0.05 to 2 at % Eu.

Preferred sintering aids include:

(i) Y₂O₃ powder with a particle size (d50) of 100 nm to 500 nm (>99.5% purity);

(ii) Al₂O₃ powder with a particle size (d50) of 100 nm to 500 nm (>99.5% purity);

(iii) SiO₂ powder with a particle size (d50) of 100 nm to 500 nm (>99.5% purity);

(iv) SiO₂ in the form of tetraethoxysilane (TEOS) (≧99% purity); and

(v) a low melting point, high refractive index glass, e.g. 50PbO-35B₂O₃-15SiO₂

For the Y₂O₃-Al₂O₃-SiO₂ system, an addition of 0.1 to 10 wt % is preferred. It is also possible to use yttrium aluminum garnet (YAG), Y₃Al₅O₁₂ (3Y₂O₃.5Al₂O₃) as the source of Y₂O₃ and Al₂O₃ and TEOS as the SiO₂ source. In particular, a preferred sintering aid composition includes for example 1.87 wt. % YAG and 4.6 wt. % TEOS. For the low melting point glass 50PbO-35B₂O₃-15SiO₂, it is possible to either (1) add a small amount, e.g., 0.1 wt. % to 5 wt. %, as a sintering aid in the SPS process; or (2) add large amount, e.g., 40 wt. %-90 wt. %, for use in a pressureless densification process.

In the SPS process, a pulsed DC current directly passes through a graphite die containing the powder compact. A preferred sintering profile includes the steps of heating the powder compact in a vacuum (<50 microns) until about 1000° C., introducing a N₂ gas, and increasing the temperature to about 1350° C. at which point a mechanical pressure of 5 to 50 MPa is applied. Final sintering is then achieved at a temperature from about 1550° C. to about 1800° C.

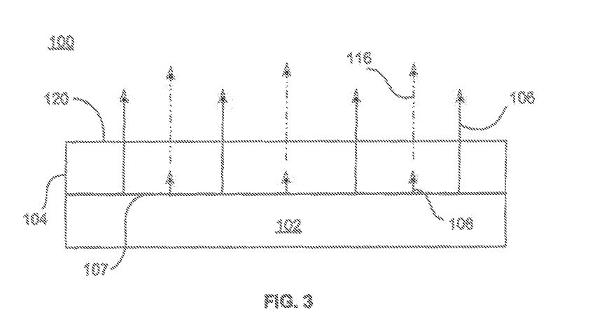

FIG. 3 illustrates the use of an α/β-SiAlON composite ceramic wavelength converter in a phosphor-converted LED (pc-LED) configuration. In particular, a light source 100 in the form of a pc-LED having a composite ceramic wavelength converter 104 is shown. The composite ceramic wavelength converter is comprised of α-SiAlON:Eu and β-SiAlON:Eu phosphors. The ceramic wavelength converter 104 generally has a thickness of between 20 μm and 500 μm and preferably between 100 μm and 250 μm. In a preferred embodiment, the ceramic converter has the shape of a flat plate, although it is not limited to such.

Primary light 106 emitted from light-emitting surface 107 of the blue-emitting LED die 102 passes into ceramic converter 104 which converts at least a portion of the blue light into a secondary light 116 having a different peak wavelength, e.g., green and red light. Preferably, the blue primary light 106 has a peak wavelength in the range of 420 nm to 490 nm. The color of the light eventually emitted from the light-emitting surface 120 of ceramic converter 104 will depend on the ratio of the amount of unconverted primary light 106 that passes through the ceramic converter to the amount of primary light that is converted to secondary light 116 within the ceramic converter. In this instance, a warm white pc-LED application is shown wherein the unconverted primary light and the converted secondary light combine to produce an overall warm white emission with a correlated color temperature (CCT) from 2000K to 4500K.

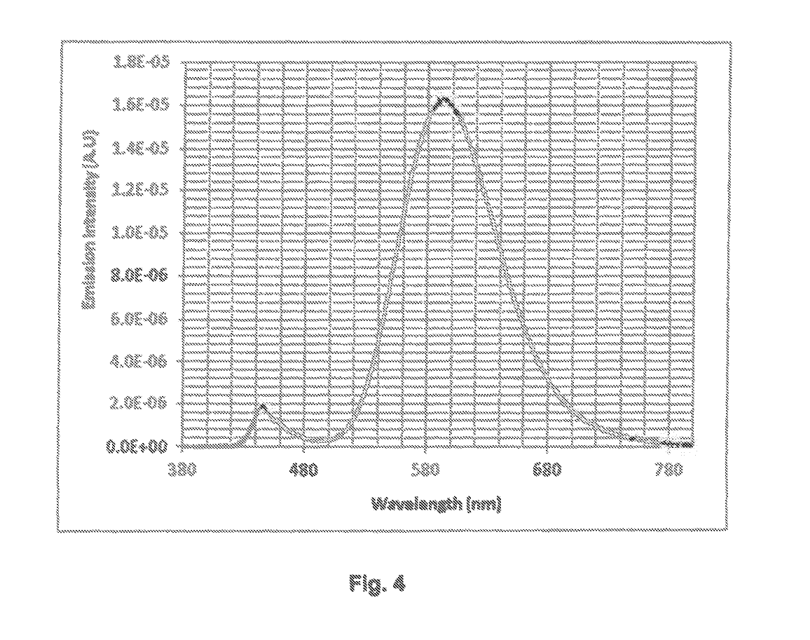

Preferably, the weight ratio of the α-SiAlON:Eu phosphor to the β-SiAlON:Eu phosphor in the composite ceramic wavelength converter is in a range of about 3:1 to about 1:3, and more preferably about 6:4 to about 3:7. In one embodiment, the composite ceramic wavelength converter comprises from about 25 to about 75 weight percent of a α-SiAlON:Eu phosphor and from about 25 to about 75 weight percent of a β-SiAlON:Eu phosphor wherein the sum of the weight percentages of the phosphors is 100%. In a preferred embodiment, the composite ceramic wavelength converter comprises from about 30 to about 60 weight percent of a α-SiAlON:Eu phosphor and from about 40 to about 70 weight percent of a β-SiAlON:Eu phosphor wherein the sum of the weight percentages of the phosphors is 100%. In another embodiment, the composite ceramic wavelength converter has from about 0.1 to about 7 weight percent of a sintering aid, and more preferably from about 0.2 to about 5 weight percent of a sintering aid. An exemplary α/β-SiAlON composite ceramic wavelength converter having a thickness of about 65 μm was shown to have a color point of (0.5210, 04351) and a CCT of 2185K demonstrating that the composite converter is a suitable for warm white applications. The spectrum of the composite is shown in FIG. 4.

While there have been shown and described what are at present considered to be preferred embodiments of the invention, it will be apparent to those skilled in the art that various changes and modifications can be made herein without departing from the scope of the invention as defined by the appended claims.

What is claimed is:

1. A composite ceramic wavelength converter having a first phase of an α-SiAlON:Eu phosphor and a second phase of a β-SiAlON:Eu phosphor.

2. The composite ceramic wavelength converter of claim 1 wherein the converter further comprises a CaAlSiN₃:Eu phosphor.

3. The composite ceramic wavelength converter of claim 1 wherein a weight ratio of the α-SiAlON:Eu phosphor to the β-SiAlON:Eu phosphor is in a range of about 3:1 to about 1:3.

4. The composite ceramic wavelength converter of claim 1 wherein a weight ratio of the α-SiAlON:Eu phosphor to the β-SiAlON:Eu phosphor is in a range of about 6:4 to about 3:7.

5. The composite ceramic wavelength converter of claim 1 wherein the composite ceramic wavelength converter comprises from about 25 to about 75 weight percent of a α-SiAlON:Eu phosphor and from about 25 to about 75 weight percent of a β-SiAlON:Eu phosphor wherein the sum of the weight percentages of the phosphors is 100%.

6. The composite ceramic wavelength converter of claim 1 wherein the composite ceramic wavelength converter comprises from about 30 to about 60 weight percent of a α-SiAlON:Eu phosphor and from about 40 to about 70 weight percent of a β-SiAlON:Eu phosphor wherein the sum of the weight percentages of the phosphors is 100%.

7. The composite ceramic wavelength converter of claim 1 wherein the composite ceramic wavelength converter further comprises from about 0.1 to about 7 weight percent of a sintering aid.

8. The composite ceramic wavelength converter of claim 1 wherein the composite ceramic wavelength converter further comprises from about 0.2 to about 5 weight percent of a sintering aid.

9. The composite ceramic wavelength converter of claim 1 wherein:
the α-SiAlON:Eu phosphor has a formula (M₁₋ₓEUₓ)_{m/v}Si₁₂₋₍ₘ₊ₙ₎Al₍ₘ₊ₙ₎OₙN₁₆₋ₙ, where M is a metal selected from Li, Ca, Mg, Y, La, Ce, Nd, Sm, Gd, Tb, Dy, and Yb, v is the valence of the metal M, 0.5≦m/v≦2, 0.001≦n≦1.8, and 0.001≦x≦0.2; and
the β-SiAlON:Eu phosphor has a formula Si_{6-z}Al_{z}O_{z}N_{8-z}:Eu, where 0.001≦z≦4.2 and the β-SiAlON:Eu phosphor contains from 0.1% to 8 mole % Eu.

10. The composite ceramic wavelength converter of claim 9 wherein 0.5≦m/v≦2, 0.001≦n≦1.0, and 0.02≦x≦0.1 in the formula for the α-SiAlON:Eu phosphor and wherein 0.1≦z≦2 in the formula for the β-SiAlON:Eu phosphor and the β-SiAlON:Eu phosphor contains from 0.2% to 4 mole % Eu.

11. The composite ceramic wavelength converter of claim 10 wherein M is Ca in the formula for the α-SiAlON:Eu phosphor.

12. The composite ceramic wavelength converter of claim 7 wherein the sintering aid comprises at least one of Y₂O₃, Al₂O₃, SiO₂ and a low melting point, high refractive index glass.

13. The composite ceramic wavelength converter of claim 7 wherein the sintering aid comprises at least one of Y₂O₃, Al₂O₃, and SiO₂.

14. A light source comprising: a light-emitting diode and a composite ceramic wavelength converter, the light-emitting diode emitting a primary light that is at least partially converted by the composite ceramic wavelength converter into a secondary light having a different wavelength, the composite ceramic wavelength converter comprising a first phase of an α-SiAlON:Eu phosphor and a second phase of a β-SiAlON:Eu phosphor wherein a weight ratio of the α-SiAlON:Eu phosphor to the β-SiAlON:Eu phosphor is in a range of about 3:1 to about 1:3.

15. The light source of claim 14 wherein the converter further comprises a CaAlSiN₃:Eu phosphor.

16. The light source of claim 14 wherein:
the α-SiAlON:Eu phosphor has a formula (M₁₋ₓEuₓ)_{m/v}Si₁₂₋₍ₘ₊ₙ₎Al₍ₘ₊ₙ₎OₙN₁₆₋ₙ, where M is a metal selected from Li, Ca, Mg, Y, La, Ce, Nd, Sm, Gd, Tb, Dy, and Yb, v is the valence of the metal M, 0.5≦m/v≦2, 0.001≦n≦1.8, and 0.001≦x≦0.2; and
the β-SiAlON:Eu phosphor has a formula Si_{6-z}Al_{z}O_{z}N_{8-z}:Eu, where 0.001≦z≦4.2 and the β-SiAlON:Eu phosphor contains from 0.1% to 8 mole % Eu.

17. The light source of claim 16 wherein 0.5≦m/v≦2, 0.001≦n≦1.0, and 0.02≦x≦0.1 in the formula for the α-SiAlON:Eu phosphor and wherein 0.1≦z≦2 in the formula for the β-SiAlON:Eu phosphor and the β-SiAlON:Eu phosphor contains from 0.2% to 4 mole % Eu.

18. The light source of claim 17 wherein M is Ca in the formula for the α-SiAlON:Eu phosphor.

19. The light source of claim 14 wherein the composite ceramic wavelength converter further comprises at least one sintering aid selected from Y₂O₃, Al₂O₃, and SiO₂.

20. The light source of claim 14 wherein the light source has a correlated color temperature (CCT) from 2000K to 4500K.
